(19) United States
(12) Patent Application Publication
(10) Pub. No.: US 2008/0224305 A1
(43) Pub. Date: Sep. 18, 2008

(54) METHOD, APPARATUS, AND SYSTEM FOR PHASE CHANGE MEMORY PACKAGING

(76) Inventor: Amip J. Shah, Mountain View, CA (US)

Correspondence Address: TROP, PRUNER & HU, P.C., 1616 S. VOSS RD., SITE 750, HOUSTON, TX, 77057-2631, US

(21) Appl. No.: 11/685,908

(22) Filed: Mar. 14, 2007

(51) Int. Cl. H01L 23/34; H01L 21/00

(52) U.S. Cl. 257/723; 438/109; 257/E23.08; 257/E21.001

(57) ABSTRACT

According to one embodiment, a die assembly is disclosed, comprising a package substrate and a plurality of stacked die on the package substrate, the plurality of stacked die including at least an uppermost die, a lowermost die, and at least one phase change memory die between the uppermost die and the lowermost die, wherein the uppermost die and lowermost die are non-functional spacer die.

### BACKGROUND

The assembly process for phase change memory packaging may include a mold process that requires the flow of a resin-based mold compound at high temperatures. For the mold process, high temperatures are achieved by heating a material to a setpoint temperature, which results in heat transfer from the high temperature material to the phase change memory die. The resulting die temperature increase can cause a phase change of the chalcogenide material in the silicon, effectively erasing bits stored in the phase change memory device.

### BRIEF DESCRIPTION OF THE DRAWINGS

A better understanding of embodiments of the present invention can be obtained from the following detailed description in conjunction with the following drawings, in which:

FIG. 1 is a block diagram illustrating a die stacking configuration for phase change memory according to some embodiments.

FIG. 2 is a block diagram illustrating a die stacking configuration according to some embodiments.

FIG. 3 is a block diagram illustrating a die stacking configuration according to some embodiments.

FIG. 4 is a graph illustrating phase change memory die temperature versus mold process time according to some embodiments.

FIG. 5 is a flow diagram illustrating a packaging process for phase change memory according to some embodiments.

FIG. 6 is an illustration of a system according to some embodiments.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure an understanding of this description.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

The term “wireless” and its derivatives may be used to describe circuits, devices, systems, methods, techniques, communications channels, etc., that communicate data by using modulated electromagnetic radiation through a non-solid medium. The term does not imply that the associated devices do not contain any wires, although in some embodiments they might not. The term “mobile wireless device” is used to describe a wireless device that may be in motion while it is communicating.

Phase change memory (PCM) is a type of non-volatile memory which uses the properties of chalcogenide material to store information. The chalcogenide may switch between an amorphous state and a crystalline state when heat is applied, thus allowing programming and/or erasure of bits within the PCM memory array. Phase change memory may also be referred to as PRAM, Ovonic Unified Memory (OUM), and Chalcogenide Random Access Memory (C-RAM).

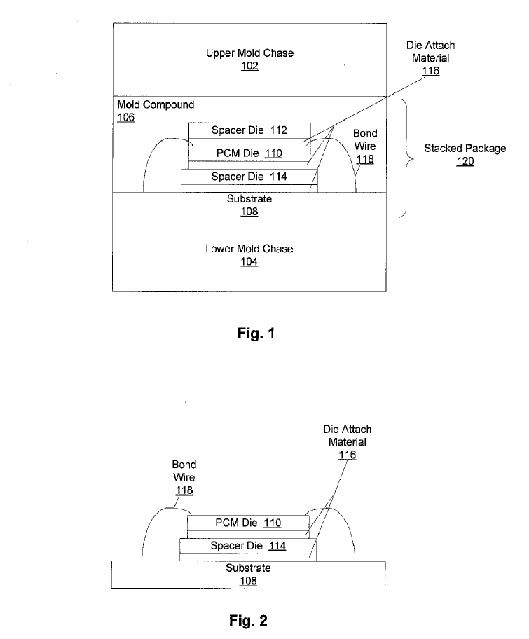

FIG. 1 is a block diagram illustrating a die stacking configuration for phase change memory (PCM) according to some embodiments. The mold process used during packaging and assembly requires the flow of a resin-based mold compound (106) at high temperatures. In some embodiments, the mold process may require temperatures of approximately 185 degrees C. to flow the mold compound.

During the mold process, an upper (102) and lower (104) mold chase are heated to a predetermined setpoint temperature (e.g., 185 degrees C.), which results in heat transfer from the high temperature mold chases to the package substrate (108), die stack (110, 112, 114), and mold compound (106).

In some embodiments, the die stack may include a lowermost spacer die (114), an uppermost spacer die (112), and at least one phase change memory die (110) between the lowermost and uppermost spacer die. The use of spacer die (112, 114) at the top and bottom of the die stack prevent heating of the phase change memory die. The large surface area of the spacer die (112, 114) cause the spacer die to have a lower thermal resistance than the phase change memory die. Thus, most of the heat from the mold chase will flow to the spacer die (112, 114). Moreover, very little surface area of the phase change memory die (110) is exposed to the mold compound, so very little heat will be transferred directly from the mold compound (106) to the phase change memory die (110).

The size and/or number of spacer die may be determined based on the amount of thermal insulation required for the phase change memory die. In some embodiments, the spacer die (112, 114) may be substantially the same size as the phase change memory die (110). In other embodiments, the spacer die may be slightly larger or slightly smaller in size than the phase change memory die. In some embodiments, multiple spacer die may be located above and/or below the phase change memory die in order to provide adequate thermal insulation. For example, additional spacer die may be located between the lowermost spacer die (114) and the phase change memory die (110). Similarly, additional spacer die may be located between the phase change memory die (110) and the uppermost spacer die (112).

In some embodiments, a layer of die attach material may be placed between die in the die stack. For example, there may be a layer of die attach material between the package substrate (108) and the lowermost spacer die (114), between the lowermost spacer die (114) and the phase change memory die (110), and between the phase change memory die (110) and the spacer die (112). The use of a thermally insulating die attach material may also aid in preventing heating of the phase change memory die. For example, as the temperature of the spacer die (112, 114) increase relative to the phase change memory die (110), some heat transfer through the die stack may be initiated. However, because the die attach material acts as an insulator, only small amounts of heat will flow through the die attach material (116) to the phase change memory die (110).

In some embodiments, the layer of thermally insulating die attach material above and below the phase change memory die may be sufficiently thick to provide thermal insulation of the phase change memory die without requiring the use of spacer die (112, 114).

The increased height of the die stack by the addition of spacer die at the top and bottom of the die stack (112, 114) also allows the usage of a smaller volume of mold compound (106) during the encapsulation process. The reduction in mold compound thermal mass implies that a smaller amount of heat must be generated in the mold cavity, which enables lowering of the upper and lower mold chase temperatures. This may allow a further reduction in temperature of the phase change memory die.

Thus, the die stacking configuration illustrated in FIG. 1 may allow molding of the phase change memory die during the packaging process at lower than typical temperatures, and may prevent the temperature of the phase change memory die from rising to a point at which bit erasure may occur due to a change in the structure of the chalcogenide material.

In some embodiments, the uppermost and/or lowermost spacer die (112, 114) may be non-functional silicon die. These die may be die from scrapped processed silicon wafers, or may be die from silicon wafers that have not yet undergone semiconductor process steps. While the phase change memory die may be electrically coupled to the package substrate by bond wires (118), the uppermost and/or lowermost spacer die may not be electrically coupled to the package substrate.

In some embodiments, one of the spacer die (112, 114) may be a functional, non-phase change memory semiconductor die. For example, one of the spacer die may be another type of non-volatile memory device, such as flash memory, a volatile memory device, or a non-memory device, such as a microprocessor, a microcontroller, a graphics device, a memory controller device, or another type of device. In this case, the functional spacer die may be electrically coupled to the package substrate (108), and in some instances, may also be electrically coupled to the phase change memory die (110). The other, nonfunctional spacer die may not be electrically coupled to the package substrate in some embodiments.

FIG. 2 is a block diagram illustrating a die stacking configuration for phase change memory (PCM) according to some embodiments. A phase change memory die (110) is stacked on a spacer die (114) on a package substrate (108). Layers of die attach material (116) may be applied between the lowermost spacer die (114) and the substrate (108), and between the phase change memory die (110) and the lowermost spacer die (114). This embodiment may be effective at preventing bit erasure during a reflow process. During a reflow process, a high temperature solder is flowed on the backside of the package (e.g., on the outer surface of the substrate) to achieve ball attach. In this case, the lowermost spacer die (114) and die attach material (116) act as insulators to prevent direct heat flow through the substrate to the phase change memory die (110). While this embodiment may not provide adequate thermal protection to the top of the phase change memory die during a mold process, it may be effective in preventing bit erasure during the packaging process if an alternative lower temperature mold process such as compression molding is used.

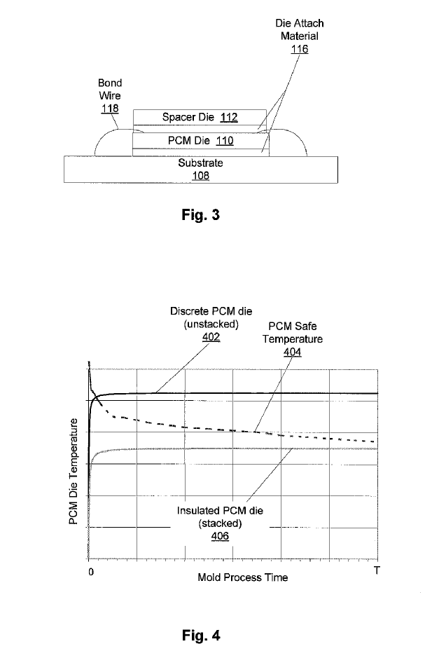

FIG. 3 is a block diagram illustrating a die stacking configuration for phase change memory (PCM) according to some embodiments. An uppermost spacer die (112) is stacked on a phase change memory die (110) on a package substrate (108). Layers of die attach material (116) may be applied between the phase change memory die (110) and the substrate (108), and between the phase change memory die (110) and the uppermost spacer die (112). This embodiment may be effective at preventing bit erasure during a plasma cleaning process. During a plasma process, the top surface of the package configuration (e.g., the top of spacer die 112 and substrate 108) may be exposed to a high temperature plasma. In this case, the uppermost spacer die (112) and die attach material (116) act as insulators to prevent direct heat flow through the spacer die (112) to the phase change memory die (110). While this embodiment may not provide adequate thermal protection to the bottom of the phase change memory die during a mold process or a reflow process, it may be effective in preventing bit erasure during the packaging process if an alternative lower temperature mold process, such as compression molding, and/or an alternative lower temperature ball attach process, such as laser ball attach, are used.

FIG. 4 is a graph illustrating phase change memory die temperature versus mold process time for a discrete phase change memory die (402) and an insulated phase change memory die (406). The phase change memory “safe” temperature is also shown (404). If the temperature of the phase change memory die rises beyond the safe temperature (404), data loss due to temperature induced bit erasure is possible. For a discrete, uninsulated phase change memory die, bit erasure may occur approximately when the temperature of the die (402) rises beyond the safe temperature (404). This may occur in a relatively short period of time. Because the mold process may require additional time to sufficiently heat and flow the mold compound, bit erasure is likely for an uninsulated phase change memory die.

As illustrated by the graph, the die temperature of an insulated phase change memory die (406) remains lower than the phase change memory safe temperature (404) for a significantly longer time than for a discrete phase change memory die (402). Thus, insulating the phase change memory die using one or more spacer die and/or die attach material may allow sufficient time to complete the mold process without causing data loss in the phase change memory due to temperature induced bit erasure.

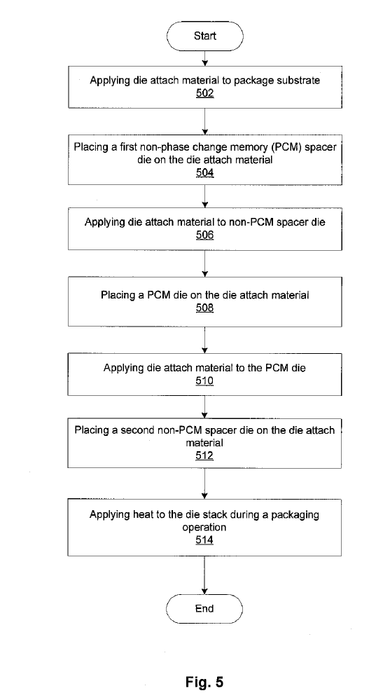

FIG. 5 is a flow diagram illustrating a packaging process for phase change memory according to some embodiments. First, a layer of die attach material may be applied to a package substrate (502). A lowermost, non-phase change memory spacer die may then be placed on the die attach material (504). As described above with respect to FIG. 1, the lowermost spacer die may be a non-functional spacer die, and may not be electrically coupled to the package substrate or other die in the package.

A second layer of die attach material may be placed on the lowermost spacer die (506). A phase change memory die may be placed on the second layer of die attach material (508). The phase change memory may be electrically coupled to the package substrate, for example, using bonding wires.

A third layer of die attach material may be placed on the phase change memory die (510). An uppermost non-phase change memory spacer die may be placed on the third layer of die attach material (514). The uppermost spacer die may be a non-functional spacer die, which may not be electrically coupled to the substrate and/or other die in the die stack.

In some embodiments, the die stack may include more or fewer die than illustrated in FIG. 5. For example, the die stack may include only an uppermost or lowermost spacer die and a phase change memory die, or may include both an uppermost and a lowermost spacer die with one or more phase change memory die and/or other functional or non-functional semiconductor die located between the uppermost and lowermost spacer die. Additionally, the die stack may include more or fewer layers of die attach material.

After the die stack has been assembled, heat may be applied to the die stack during a packaging operation (514). In some embodiments, the packaging operation may be a mold operation. In other embodiments, the packaging operation may be a plasma operation or reflow operation.

The use of the uppermost and/or lowermost spacer die will protect the phase change memory die from heat induced bit erasure during packaging process. This may eliminate the need to re-test and/or re-program the phase change memory die after a high temperature operation during the packaging process. Additionally, because there is no danger of heat-induced data loss, the die may be pre-programmed prior to assembly. Finally, the ability to use high temperature processes (e.g., greater than 140 degrees C.) in the phase change memory packaging process may eliminate capital costs incurred by a migration to lower temperature processes.

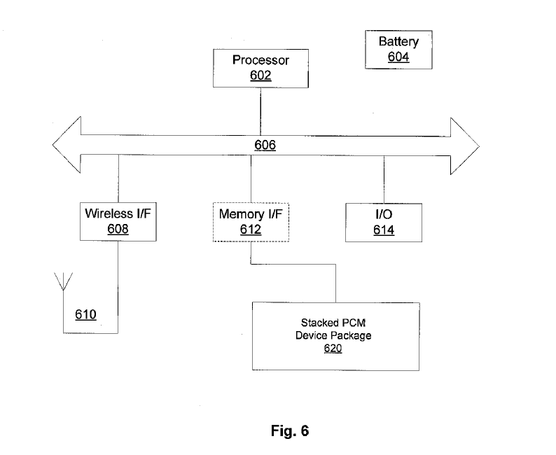

FIG. 6 is a block diagram of a system according to one embodiment, In some embodiments, the system may be a mobile wireless device.

The system may include a processor (602) which communicates via an interconnect (606). The processor (602) may be a microcontroller, one or more microprocessors, each of which may include one or more cores, a digital signal processor (DSP), or another type of controller. The system may be powered by a battery (604) or may be powered with another power source, such as AC power.

A variety of input/output (I/O) devices (614) may be coupled to the interconnect (606). The I/O devices may include items such as a display, keyboard, mouse, touch screen, or other I/O devices. A wireless network interface (608) including an antenna (610) may also be coupled to the interconnect (606). The wireless interface (608) may enable cellular or other wireless communication between the system and other devices. In one embodiment, the antenna (610) may be a dipole antenna.

The system also includes a phase change memory device in a stacked package (620). The stacked phase change memory device package may have a die stack such as that described above with respect to FIG. 1, 2, 3, or 5. The memory device may be built into the system, or may be part of a removable storage medium, such as a card form factor, that may be inserted into an optional memory card interface (612) or other type of interface.

In some embodiments, the stacked phase change memory device (620) may include a phase change memory die stacked between an uppermost and a lowermost spacer die. The die stack may also include one or more layers of a die attach material. The stacked phase change memory device (620) may include other elements as well, however, those components are not illustrated here for ease of understanding.

Thus, a method, apparatus, and system for phase change memory packaging are disclosed in various embodiments. In the above description, numerous specific details are set forth. However, it is understood that embodiments may be practiced without these specific details. In other instances, well-known circuits, structures, and techniques have not been shown in detail in order not to obscure the understanding of this description. Embodiments have been described with reference to specific exemplary embodiments thereof. It will, however, be evident to persons having the benefit of this disclosure that various modifications and changes may be made to these embodiments without departing from the broader spirit and scope of the embodiments described herein. The specification and drawings are, accordingly, to be regarded in an illustrative rather than a restrictive sense.

We claim:

1. An apparatus comprising:
a package substrate; and
a plurality of stacked die on the package substrate, the plurality of stacked die including at least an uppermost die, a lowermost die, and at least one phase change memory die between the uppermost die and the lowermost die, wherein the uppermost die and lowermost die are spacer die.

2. The apparatus of claim 1, further comprising a plurality of layers of a die attach material, wherein one of the plurality of layers of the die attach material is between the package substrate and the lowermost die, and each of the other layers of die attach material are between stacked die.

3. The apparatus of claim 2, wherein the uppermost die and the lowermost die are not electrically coupled to the package substrate.

4. The apparatus of claim 2, wherein the uppermost die and the lowermost die are non-operational die.

5. The apparatus of claim 2, wherein one of the uppermost die and the lowermost die is an operational device and wherein the other of the uppermost die and the lowermost die is a non-operational die.

6. The apparatus of claim 1, wherein the uppermost die and the lowermost die are to protect the at least one phase change memory die from heat induced bit erasure during a packaging process.

7. A method comprising:
stacking a plurality of die on a package substrate, the plurality of die including a lowermost die, an uppermost die, and at least one phase change memory die between the uppermost and lowermost die; and
applying heat to the plurality of die during a packaging operation.

8. The method of claim 7, wherein the uppermost die and the lowermost die are not electrically coupled to the package substrate.

9. The method of claim 7, wherein one of the uppermost die and the lowermost die is an operational device and wherein the other of the uppermost die and the lowermost die is a non-operational device.

10. The method of claim 7, wherein the packaging operation is a mold operation.

11. The method of claim 7, wherein the packaging operation is a plasma operation.

12. The method of claim 7, wherein the packaging operation is a reflow operation.

13. A method, comprising:
applying a first layer of die attach material to a substrate;
stacking a first spacer die on the first layer of die attach material;
applying a second layer of die attach material to the first spacer die;
stacking a phase change memory die on the second layer of die attach material to form a die stack; and
applying heat to the die stack during a packaging operation.

14. The method of claim 13, wherein the packaging operation is a reflow operation.

15. The method of claim 13, further comprising applying a third layer of die attach material to the phase change memory die and stacking a second spacer die on the third layer of die attach material before applying heat to the die stack during a packaging operation.

16. The method of claim 15, wherein the packaging operation is a mold operation.

17. The method of claim 15, wherein the phase change memory die is electrically coupled to the substrate and wherein the first spacer die and the second spacer die are not electrically coupled to the substrate.

18. A system, comprising:
an interconnect;
a processor coupled to the interconnect;
a wireless interface coupled to the interconnect; and
a phase change memory device coupled to the interconnect, wherein the phase change memory device is part of a package including a lowermost spacer die and an uppermost spacer die, and wherein the phase change memory device is physically positioned between the uppermost spacer die and the lowermost spacer die.

19. The system of claim 18, wherein the package further includes a first layer of die attach material between the phase change memory device and the uppermost spacer die and a second layer of die attach material between the phase change memory device and the lowermost spacer die.

20. The system of claim 18, wherein the uppermost spacer die and the lowermost spacer die are not electrically coupled to the package substrate.
